(19) United States
(12) Patent Application Publication
(10) Pub. No.: US 2003/0076067 A1
(43) Pub. Date: Apr. 24, 2003

(54) Method and apparatus for electronically controlling a motorized device

(76) Inventors: C. Rucker Ashmore, Horseshoe Bay, TX (US); Toan D. Pham, Cedar Park, TX (US)

Correspondence Address: CALFEE HALTER & GRISWOLD, LLP, 800 SUPERIOR AVENUE, SUITE 1400, CLEVELAND, OH, 44114, US

(21) Appl. No.: 10/273,320

(22) Filed: Oct. 17, 2002

Related U.S. Application Data
(60) Provisional application No. 60/343,872, filed on Oct. 19, 2001.

(51) Int. Cl. G05B 1/06; G01R 27/26

(52) U.S. Cl. 318/662; 324/686

(57) ABSTRACT

An electronic controller for a motorized device includes a signal generator generating an output signal to the motorized device. A non-proportional proximity sensor communicates with the signal generator. A proportional proximity sensor communicates with the signal generator. The output signal is determined as a function of respective signals communicated from the proximity sensors to the signal generator. A direction and speed of the motorized device is determined as a function of the output signal.

This application claims the benefit of U.S. Provisional Application No. 60/343,872, filed Oct. 19, 2001.

### STATEMENT REGARDING FEDERALLY SPONSORED RESEARCH AND DEVELOPMENT

This invention was not made by an agency of the United States Government nor under contract with an agency of the United States Government.

### BACKGROUND OF THE INVENTION

The present invention relates to a microprocessing device used in conjunction with capacitive elements for sensing a position of an object and producing an output signal as a function of the position. It finds particular application in conjunction with controlling the operation of a motorized wheelchair and will be described with particular reference thereto. It will be appreciated, however, that the invention is also amenable to other like applications.

A wheelchair enables a disabled person, whose ability to move is restricted, to move about from place to place with an added degree of freedom. Conventional motorized wheelchairs enable a user to move by manipulating a few wheelchair controls. Wheelchair controls are typically hand operated devices. However, wheelchair controls adapted for special needs have been designed for wheelchair users who do not have use of their hands to operate the controls.

Such wheelchair controls adapted for special needs have been addressed, in part, by providing wheelchair control systems that rely on controlled movements of other body parts of a user (e.g., controls operated by a leg, chin, or head). Controls that utilize movement of the head to activate wheelchair controls exist which use reflecting mirrors attached to the head and movable with the head while others use ultrasonic techniques to bounce sound waves from the head and thus determine its position for controlling the wheelchair. Wheelchair control systems of these types are described in U.S. Pat. Nos. 3,374,845; 3,965,402; 3,993,154; 4,281,734; 4,093,037; and 4,679,644.

U.S. Pat. No. 3,761,736 describes a proximity switch operating on a capacitance principle to detect changes in capacitance occurring when an object comes in close proximity to the switch. Capacitance principles are also employed in the apparatus of U.S. Pat. No. 3,993,154 wherein a low-power signal is carried by a conductor to a thin conductive metal foil located in a back rest portion of a motorized wheelchair. One drawback of sensing circuits used for these types of wheelchair controls is that contact with the body is required. Such contact may take the form of a helmet or mirrors attached to the head or actual physical body contact with a part of a wheelchair.

U.S. Pat. No. 4,767,940 (“the '940 patent”), which is hereby incorporated by reference, discloses a sensing circuit for a wheelchair control that does not require physical contact with the user's body and does not hinder the user's field of vision or mobility. However, that sensing circuit incorporates proportional signals from sensors for controlling both forward/reverse movements and left/right turns of the wheelchair and, furthermore, requires relatively complicated circuitry.

Users of power wheelchairs often times do not have a great amount of control over their head (or other body parts) for controlling the wheelchair. Furthermore, such persons often times have significantly less control over side-to-side movements of the head, which are typically used for turning the wheelchair to the left and right, than front-to-rear movements, which are typically used for moving the wheelchair forward and backward. Consequently, a user may be capable of performing proportional movements to the front and rear for achieving an acceptable level of control over both the speed and direction while moving the wheelchair forward and/or backward. However, it is not uncommon that the same user may not be capable of performing side-to-side proportional movements for achieving an acceptable level of control over both the speed and direction while moving the wheelchair left and/or right. For these reasons, proportional capacitive proximity sensors are desirable for sensing front-to-rear movements, but not side-to-side movements, of a users head.

The present invention provides a new and improved apparatus and method which addresses the above-referenced problems.

### SUMMARY OF THE INVENTION

An electronic controller for a motorized device includes a signal generator generating an output signal to the motorized device. A non-proportional proximity sensor communicates with the signal generator. A proportional proximity sensor communicates with the signal generator. The output signal is determined as a function of respective signals communicated from the proximity sensors to the signal generator. A direction and speed of the motorized device is determined as a function of the output signal.

In one aspect, each of the proximity sensors is a capacitive sensor.

In another aspect, an analog-to-digital converter converts the respective signals from each of the proximity sensors from an analog format to a digital format. The digital format of the respective signals is communicated to the signal generator.

In another aspect, a second non-proportional proximity sensor communicates with the signal generator. The output signal is determined as a function of respective signals communicated from each of the proximity sensors to the signal generator. The proximity sensors are formed into an array.

In another aspect, the array is positioned around a movable bodypart of a user transported by the motorized device.

In another aspect, the body part is a head.

In another aspect, if the body part is within an operating range of the first non-proportional proximity sensor, the signal communicated from the first non-proportional proximity sensor to the signal generator includes one of a left-turn and a right-turn indicator. If the body part is within an operating range of the second non-proportional proximity sensor, the signal communicated from the second non-proportional proximity sensor to the signal generator includes the other of a left-turn and a right-turn; indicator. The signal communicated from the proportional proximity sensor indicates a distance of the body part from the proportional proximity sensor. The speed is set as a function of the distance of the body part from the proportional proximity sensor. The direction is set as a function of the left-turn and right-turn indicators.

In another aspect, if the distance of the body part from the proportional proximity sensor is beyond a predetermined limit, the speed is set to zero.

In another aspect, if one of the left-turn and right-turn indicators is included in the signals communicated to the signal generator, the direction is set between 0° and ±90°.

In another embodiment, a powered vehicle for transporting a passenger includes a first proximity sensor generating a direction signal and a second proximity sensor generating a speed signal. A controller generates an output signal for moving the vehicle in a direction and at a speed as a function of the direction and speed signals, respectively.

In another embodiment, a method for controlling a motorized device includes generating a first direction signal as a function of a distance of an object relative to a first, non-proportional sensor. A speed signal is generated as a function of a distance of the object relative to a second, proportional sensor. An output signal is generated for controlling the device as a function of the first direction and speed signals.

### BRIEF DESCRIPTION OF THE DRAWINGS

In the accompanying drawings which are incorporated in and constitute a part of the specification, embodiments of the invention are illustrated, which, together with a general description of the invention given above, and the detailed description given below, serve to exemplify the embodiments of this invention.

FIG. 1 illustrates a perspective view of the motorized device according to the present invention;

FIG. 2 illustrates a front view of the sensor module according to the present invention;

FIG. 3 illustrates a side view of the sensor module according to the present invention; and

FIG. 4 illustrates a flow-chart of the operation of the motorized device according to the present invention.

### DETAILED DESCRIPTION OF ILLUSTRATED EMBODIMENT

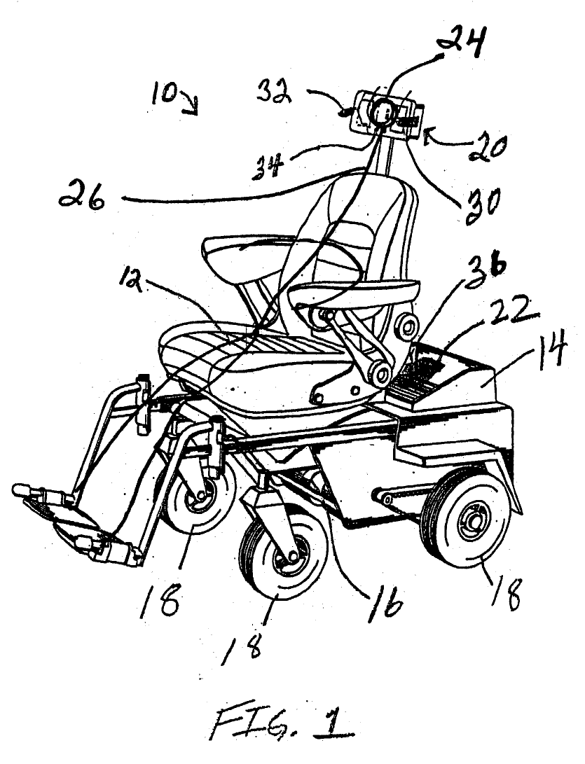

With reference to FIG. 1, a motorized device 10 (e.g., a vehicle such as a wheelchair) according to the present invention includes a seat portion 12, which accommodates a user (e.g., a passenger) 15, a housing 14, which accommodates a motor 16 for moving the device 10, wheels 18, a sensor module 20, and a control module 22. The wheels 18 are mechanically connected to the motor 16 in a conventional manner such that the device 10 moves when the motor 16 causes the wheels 18 to turn. The control module 22 is electrically connected to the motor 16 such that control signals, which cause the motor 16 to turn the wheels 18 at respective speeds, are received in the motor 16 from the control module 22. The sensor module 20 electrically communicates with the control module 22. Sensor signals transmitted from the sensor module 20 to the control module 22 are transformed within the control module 22 into the control signals, which are transmitted to the motor 16.

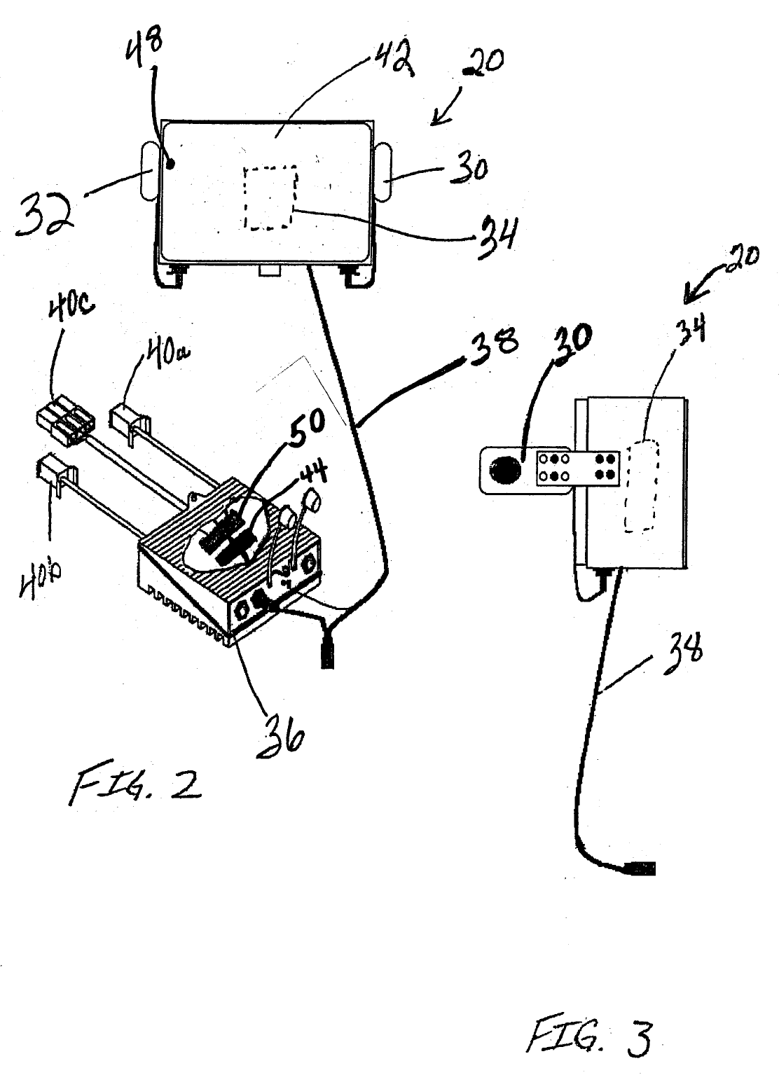

FIGS. 2 and 3 illustrate front and side views, respectively, of the sensor module 20. In this embodiment, the sensor module 20 is illustrated as an array around a head 24 of a user 26; however, other embodiments, in which the sensor module 20 is configured for other objects (e.g., movable body parts 24 of a user 26 (e.g., hand, arm, leg, and/or foot)), are also contemplated. The sensor module 20 includes a plurality of capacitive proximity sensors 30, 32, 34 and a sensor adapter 36. The sensors 30, 32, 34 communicate with the adapter 36 via an electrical connector (e.g., cable) 38. Connectors 40a, 40b, 40c mate with the control module 22 for transmitting signals between the adapter 36 and the control module 22.

The sensors 30, 32 represent non-proportional side (e.g., left and right, respectively) proximity sensors, which act as on/off switches, while the sensor 34 represents a proportional center proximity sensor. The sensor 34 is optionally covered by a pad 42 (e.g.,. foam pad) and, therefore, is hidden from plain view and illustrated using dashed lines. It is to be understood in this embodiment, the head of the user is positioned within the array 20 of sensors 30, 32, 34 such that the non-proportional side proximity sensors 30, 32 are positioned on the left and right sides, respectively, of the head and the proportional center proximity sensor 34 is positioned behind the head.

The non-proportional proximity sensors 30, 32 are contemplated in one embodiment to have a predetermined operating range (e.g., about ⅜″). More specifically, the sensors 30, 32 detect the presence of the body part 24 (e.g., the head) when the body part is within the predetermined operating range (e.g., about ⅜″ or closer to the sensors 30, 32). The respective sensors 30, 32 turn to an “ON” mode when the presence of the body part is detected; otherwise, the sensors 30, 32 are in an “OFF” mode. In one embodiment, the non-proportional proximity sensors 30, 32 are manufactured by Omron and are identified as part number E2K-F10MC1; however, other non-proportional proximity sensors are also contemplated.

The proportional proximity sensor 34 transits a signal to the adapter 36 as a function of a distance between the sensor and the body part 24. In one embodiment, the proportional proximity sensor 34 has a longer range relative to the non-proportional proximity sensors 30, 32. For example, it is contemplated in one embodiment that the proportional proximity sensor 34 has a range of about 2½″. In this case, the sensor 34 creates a signal proportional to a distance of the body part 24 from the sensor 34 over the range of about 2½″. One example of the proportional proximity sensor 34 is embodied in the '940 patent; however, other proportional proximity sensors 34 are also contemplated.

In one embodiment, the signals transmitted from the sensors 30, 32, 34 to the adapter 36 are in an analog format. An analog-to-digital converter 44 within the adapter 36 transforms the analog signals from the sensors 30, 32, 34 to respective signals having digital formats. Other embodiments, in which the signals transmitted from the sensors 30, 32, 34 to the adapter 36 are in a digital format are also contemplated.

The digital signals from the converter 44 are transmitted to a controller 50 (e.g., an electronic microprocessor or microcontroller). The controller 50 generates an output signal as a function of the signals received from the converter 44. In this sense, the controller 50 is a signal generator. More specifically, the controller 50 determines a speed as a function of the signal received from the proportional proximity sensor 34 and directional information as a function of the signal received from the non-proportional sensors 30, 32.

If the signal transmitted from the left non-proportional proximity sensor 30 indicates the body part 24 is within the predetermined operating range of the sensor 30 (e.g., the body part is within ⅜″ of the proximity sensor 30), a directional component of the output signal includes a left turn signal. If the signal transmitted from the right non-proportional proximity sensor 32 indicates the body part 24 is within the predetermined operating range of the sensor 32 (e.g., the body part is within ⅜″ of the proximity sensor 32), a directional component of the output signal includes a right turn signal. If neither the left proportional sensors 30 nor the right non-proportional sensor 32 indicates the body part 24 is within the predetermined operating ranges of the respective sensors 30, 32, a directional component of the output signal includes a no-turn (e.g., straight) signal. If both the left and right non-proportional sensors 30, 32 indicate the body part 24 is within the predetermined operating ranges of the respective sensors 30, 32, an error code is generated within the adapter 36 and a speed component of the output signal includes a command to stop the device 10. Otherwise, the speed component of the output signal includes a signal determined as a function of a distance between the body part 24 and the proportional proximity sensor 34. The output signal is transmitted from the controller 50 to the control module 22.

If the directional component of the output signal includes one of the left and right turn signals, the control module 22 causes the device to veer (e.g., turn at about 45°) towards the respective direction at a speed determined as a function of the distance of the body part from the proportional proximity sensor 34. Importantly, because the left and right proximity sensors 30, 32 are non-proportional, the direction of the device 10 is merely set as “LEFT,” “RIGHT,” or “STRAIGHT.” In other words, the direction of the of the device 10 is not set as a function of the distance between the body part and the left and right proximity sensors 30, 32 and, instead, veers left if the body part is within the predetermined operating range of the left sensor 30 and veers right if the body part is within the predetermined operating range of the right sensor 32. Although it is contemplated the angle of the veer is about 45° in either the left or right direction, other angles (e.g., in the range of 0±180°) are also contemplated. Furthermore, the angle of the veer is previously set within the control module 22.

It is to be understood that the sensor module 20 optionally includes a switch 48 that may be operated by the user's body part for changing the drive direction of the device 20 between forward and reverse modes. More specifically, it the device 10 is in a first mode (e.g., the forward mode) and the user desires to switch to a second mode (e.g., the reverse mode), the user may move his/her body part to activate the switch to change modes. It is to be understood the user may switch between modes as desired. In one embodiment, the switch is contemplated to be a single-pole double-through switch; however, a toggle switch, or any other type of switch, is also contemplated.

It is also contemplated in other embodiments that the user may change the direction of the device 20 by moving his/her body part 24 in a predetermined pattern relative to one of the sensors 30, 32, 34. For example, the user 26 may change the direction of the device by moving the body part within and out of the predetermined operating range of each of the sensors 32, 34 within a predetermined time period (e.g., the user could move his head from left to right a predetermined number of times within a predetermined time period).

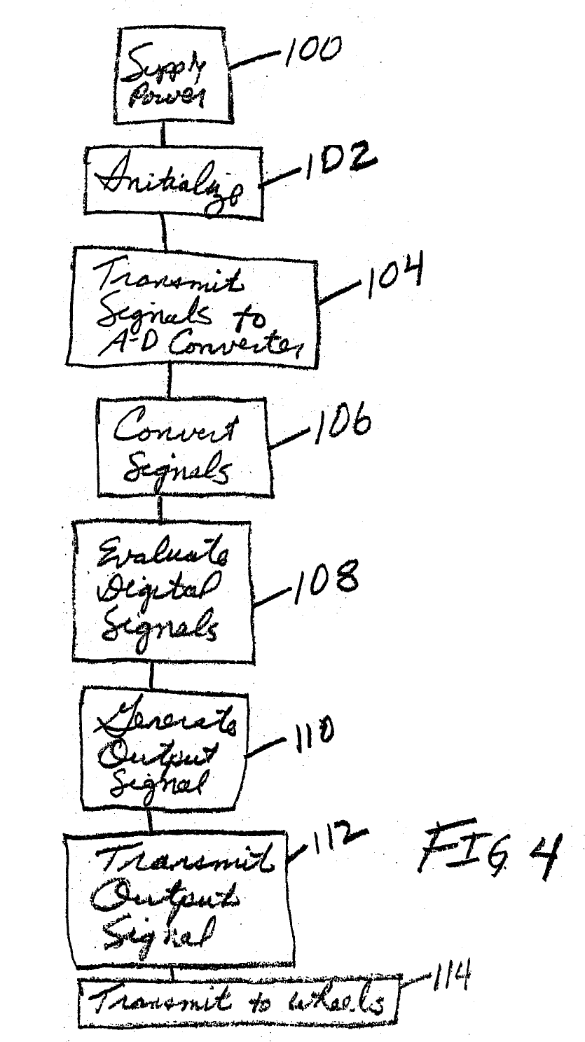

With reference to FIG. 4, power is supplied to the device 10 in a block 100. The sensor module 20, including the analog-to-digital converter 44 and the controller 50, is initialized in a block 102. The signals are transmitted, in a block 104, from the sensors 30, 32, 34 to the analog-to-digital converter 44 in the adapter 36. The signals are converted from the analog format to the digital format in a block 106. The digital signals are transmitted to the controller 50 and evaluated in a block 108. More specifically, the speed and whether a left and/or a right turn is indicated are determined in the block 108.

The output signal is generated in a block 110 as a function of the determination made in the block 108. One component of the output signal represents the direction of the device 10. More specifically, if a left turn is indicated by the sensor 30 and a right turn is not indicated by the sensor 32, the direction component of the output signal indicates a left turn. Conversely, if a left turn is not indicated by the sensor 30 and a right turn is indicated by the sensor 32, the directions component of the output signal indicates a right turn. Another component of the output signal represents the speed of the device 10. More specifically, the speed component of the output signal indicates a speed proportional to the distance of the body part from the center sensor 34; for example, a higher speed is indicated the farther the body part is from the sensor 34. However, if the body part is beyond a predetermined limit past the predetermined operating range of the sensor 30 (e.g., beyond the 5″ from the center sensor 34) and/or if the sensors 30, 32 call for both a left and a right turn, the speed component of the output signal is set to zero (0). This “autostop” safeguard helps reduce the risk of injury to the user. However, the use of the “autostop” feature is optional. If the “autostop” feature is not used, the device 10 will move a predetermined speed (e.g., the maximum speed) if the body part is moved beyond the predetermined limit (e.g., beyond the 2½″) from the center sensor 34.

The output signal is transmitted from the controller 50 to the control module 22 in a block 112. The control module 22 sends control signals to the wheels 18, in a block 114, as a function of the output signal. If a left or right turn signal is included in the direction component of the output signal, the wheels are controlled to cause the device to veer at a predetermined angle (e.g., 45°) toward the left or right side, respectively, while the speed of the device 10 is set as a function of the speed component of the output signal.

In one embodiment, the speed of the wheels 18 is set independently of the direction. Therefore, the device 10 can veer at any speed; the determination of whether the device 10 veers is made as a function of the distance of the body part from the sensors 30, 32 while the determination of the speed is made as a function of the distance of the body part from the center sensor 34.

While the present invention has been illustrated by the description of embodiments thereof, and while the embodiments have been described in considerable detail, it is not the intention of the applicants to restrict or in any way limit the scope of the appended claims to such detail. Additional advantages and modifications will readily appear to those skilled in the art. Therefore, the invention, in its broader aspects, is not limited to the specific details, the representative apparatus, and illustrative examples shown and described. Accordingly, departures may be made from such details without departing from the spirit or scope of the applicant's general inventive concept.

We claim:

1. An electronic controller for a motorized device, comprising:
a signal generator generating an output signal to the motorized device;
a non-proportional proximity sensor communicating with the signal generator; and
a proportional proximity sensor communicating with the signal generator, the output signal being determined as a function of respective signals communicated from the proximity sensors to the signal generator, a direction and speed of the motorized device being determined as a function of the output signal.

2. The electronic controller as set forth in claim 1, wherein each of the proximity sensors is a capacitive sensor.

3. The electronic controller as set forth in claim 1, further including:
an analog-to-digital converter for converting the respective signals from each of the proximity sensors from an analog format to a digital format, the digital format of the respective signals being communicated to the signal generator.

4. The electronic controller as set forth in claim 1, further including:
a second non-proportional proximity sensor communicating with the signal generator;
wherein the output signal is determined as a function of respective signals communicated from each of the proximity sensors to the signal generator; and
wherein the proximity sensors are formed into an array.

5. The electronic controller as set forth in claim 4, wherein the array is positioned around a movable body part of a user transported by the motorized device.

6. The electronic controller as set forth in claim 5, wherein the body part is a head.

7. The electronic controller as set forth in claim 5, wherein:
if the body part is within an operating range of the first non-proportional proximity sensor, the signal communicated from the first non-proportional proximity sensor to the signal generator includes one of a left-turn and a right-turn indicator;
if the body part is within an operating range of the second non-proportional proximity sensor, the signal communicated from the second non-proportional proximity sensor to the signal generator includes the other of a left-turn and a right-turn indicator;
the signal communicated from the proportional proximity sensor indicates a distance of the body part from the proportional proximity sensor;
the speed is set as a function of the distance of the body part from the proportional proximity sensor; and
the direction is set as a function of the left-turn and right-turn indicators.

8. The electronic controller as set forth in claim 7, wherein if the distance of the body part from the proportional proximity sensor is beyond a predetermined limit, the speed is set to zero.

9. The electronic controller as set forth in claim 7, wherein if one of the left-turn and right-turn indicators is included in the signals communicated to the signal generator, the direction is set between 0° and ±90°.

10. A powered vehicle for transporting a passenger, the vehicle comprising:
a first proximity sensor generating a direction signal;
a second proximity sensor generating a speed signal; and
a controller generating an output signal for moving the vehicle in a direction and at a speed as a function of the direction and speed signals, respectively.

11. The powered vehicle as set forth in claim 10, wherein:
the first proximity sensor is a non-proportional sensor; and
the second proximity sensor is a proportional sensor.

12. The powered vehicle as set forth in claim 11, further including:
a third, non-proportional proximity sensor generating a second direction signal and communicating with the controller; and
wherein the output signal is determined as a function of respective signals communicated from each of the proximity sensors to the controller.

13. The powered vehicle as set forth in claim 12, wherein the proximity sensors are formed into an array.

14. The powered vehicle as set forth in claim 12, wherein each of the proximity sensors is a capacitive sensor.

15. The powered vehicle as set forth in claim 12, wherein:
the proximity sensors generate analog signals, which are transmitted to an analog-to-digital converter;
the analog-to-digital converter converts the analog signals into respective digital signals, which are transmitted to the controller.

16. The powered vehicle as set forth in claim 12, wherein:
if the passenger is within an operating range of the first proximity sensor, the signal communicated from the first proximity sensor to the controller includes one of a left-turn and a right-turn indicator;
if the passenger is within an operating range of the third proximity sensor, the signal communicated from the third proximity sensor to the controller includes the other of a left-turn and a right-turn indicator;
the signal communicated from the second proximity sensor indicates a distance of the body part from the proportional proximity sensor;
the output signal causes the speed of the vehicle to be set as a function of the distance of the passenger from the second proximity sensor; and
the output signal causes the direction of the vehicle to be set as a function of the left-turn and right-turn indicators.

17. The powered vehicle as set forth in claim 10, further including:
a switch for changing a drive direction between a forward mode and a reverse mode.

18. A method for controlling a motorized device, the method comprising:
generating a first direction signal as a function of a distance of an object relative to a first, non-proportional sensor;
generating a speed signal as a function of a distance of the object relative to a second, proportional sensor; and
generating an output signal for controlling the device as a function of the first direction and speed signals.

19. The method for controlling a motorized device as set forth in claim 18, further including:
generating a second direction signal as a function of a distance of the object relative to a third, non-proportional sensor; and
generating the output signal as a function of the first and second direction signals and the speed signal.

20. The method for controlling a motorized device as set forth in claim 19, wherein:
if the object is within an operating range of the first sensor, generating the first direction signal as one of a left-turn and a right-turn indicator;
if the object is within an operating range of the third sensor, generating the second direction signal as the other of a left-turn and a right-turn indicator;
setting the speed of the motorized device as a function of the speed signal; and
setting the direction of the, motorized device as a function of the first and second direction signals.

21. The method for controlling a motorized device as set forth in claim 20, further including:
if the distance of the object from the second sensor is beyond a predetermined limit, setting the speed to zero.

22. The method for controlling a motorized device as set forth in claim 18, further including:
forming the sensors into an array.

23. The method for controlling a motorized device as set forth in claim 22, further including:
positioning the array around a movable body part of a user transported by the motorized device.

24. The method for controlling a motorized device as set forth in claim 18, further including:
changing a drive direction between a forward mode and a reverse mode.
